(19) United States
(12) Patent Application Publication
(10) Pub. No.: US 2025/0226300 A1
(43) Pub. Date: Jul. 10, 2025

(54) ELECTRONIC DEVICE

(71) Applicant: Innolux Corporation, Miaoli County (TW)

(72) Inventor: Po-Yun Hsu, Miaoli County (TW)

(73) Assignee: Innolux Corporation, Miaoli County (TW)

(21) Appl. No.: 18/974,844

(22) Filed: Dec. 10, 2024

Related U.S. Application Data
(60) Provisional application No. 63/617,768, filed on Jan. 5, 2024.

(30) Foreign Application Priority Data
Sep. 10, 2024 (CN) 202411263685.9

(51) Int. Cl. H01L 23/498; H01L 23/15

(52) U.S. Cl. CPC H01L 23/49822; H01L 23/49838; H01L 23/49894; H01L 23/15

(57) ABSTRACT

An electronic device includes a substrate, a through hole, a buffer layer, a first circuit structure, and an electronic component. The substrate includes a first side and a second side opposite to the first side. The through hole penetrates the substrate. The buffer layer is disposed on the first side of the substrate, the second side of the substrate, and an inner wall of the through hole. The first circuit structure is disposed on the first side. The electronic component is disposed on the first circuit structure. The buffer layer includes a plurality of layers.

### CROSS-REFERENCE TO RELATED APPLICATION

This application claims the priority benefit of U.S. provisional application Ser. No. 63/617,768, filed on Jan. 5, 2024 and China application serial no. 202411263685.9, filed on Sep. 10, 2024. The entirety of each of the above-mentioned patent applications is hereby incorporated by reference herein and made a part of this specification.

### BACKGROUND

### Technical Field

The disclosure relates to an electronic device, and in particular, relates to an electronic device capable of enhancing the structural strength of a substrate or may enhancing the adhesion capability between the substrate and other film layers.

### Description of Related Art

Electronic devices or spliced electronic devices including semiconductor components have been widely applied in various fields such as communication, display, vehicles, or aviation. With the vigorous advancement of electronic devices, the development of the electronic devices moves towards thinness and lightness. Therefore, the requirements for reliability and quality of the electronic devices continue to grow.

### SUMMARY

The disclosure provides an electronic device capable of enhancing structural strength of a substrate or an adhesion capability between the substrate and other film layers.

According to an embodiment of the disclosure, an electronic device includes a substrate, a through hole, a buffer layer, a first circuit structure, and an electronic component. The substrate includes a first side and a second side opposite to the first side. The through hole penetrates the substrate. The buffer layer is disposed on the first side of the substrate, the second side of the substrate, and an inner wall of the through hole. The first circuit structure is disposed on the first side. The electronic component is disposed on the first circuit structure. The buffer layer includes a plurality of layers.

### BRIEF DESCRIPTION OF THE DRAWINGS

The accompanying drawings are included to provide a further understanding of the disclosure, and the accompanying drawings are incorporated in and constitute a part of this specification. The drawings illustrate the embodiments of the disclosure, and together with the description, serve to explain the principle of the disclosure.

FIG. 1A is a cross-sectional schematic view of an electronic device according to a first embodiment of the disclosure.

FIG. 1B is a schematic top view of a through hole in the electronic device of FIG. 1A.

FIG. 2 is an enlarged schematic view of a region R1 in FIG. 1A.

FIG. 3 is a cross-sectional schematic view of an electronic device according to a second embodiment of the disclosure.

FIG. 4 is an enlarged schematic view of a region R2 in FIG. 3.

FIG. 5 is a cross-sectional schematic view of an electronic device according to a third embodiment of the disclosure.

FIG. 6 is a cross-sectional schematic view of an electronic device according to a fourth embodiment of the disclosure.

FIG. 7 is a cross-sectional schematic view of an electronic device according to a fifth embodiment of the disclosure.

FIG. 8A is a cross-sectional schematic view of an electronic device according to a sixth embodiment of the disclosure.

FIG. 8B is an enlarged schematic view of a region R3 in FIG. 8A.

### DESCRIPTION OF THE EMBODIMENTS

The accompanying drawings are included together with the detailed description provided below to provide a further understanding of the disclosure. Note that in order to make the accompanying drawings to be more comprehensible to readers and for the sake of clarity of the accompanying drawings, only part of the electronic device is depicted in the accompanying drawings of the disclosure, and specific elements in the drawings are not depicted according to actual scales. Moreover, the quantity and the size of each device in the drawings are only schematic and exemplary and are not intended to limit the scope of protection provided in the disclosure.

In the following specification and claims, the words “containing” and “including” are open-ended words and therefore should be interpreted as “containing but not limited to . . . ”.

It should be understood that when an element or a film layer is referred to as being “on” or “connected to” another element or film layer, it can be directly on the another element or film layer or be directly connected to the another element or film layer, or an inserted element or film layer may be provided therebetween (not a direct connection). In contrast, when the element is referred to as being “directly on” another element or film layer or “directly connected to” another element or film layer, an inserted element or film layer is not provided therebetween.

Although the terms “first”, “second”, “third” . . . may be used to describe various constituent elements, the constituent elements are not limited to these terms. These terms are only used to distinguish a single constituent element from other constituent elements in the specification. The same terms may not be used in the claims, and the elements in the claims may be replaced with first, second, third . . . according to the order declared by the elements in the claims. Therefore, in the following description, the first constituent element may be the second constituent element in the claims.

In the text, the terms “about”, “approximately”, “substantially”, and “roughly” usually mean within 10%, 5%, 3%, 2%, 1%, or 0.5% of a given value or range. The number given here is an approximate number, that is, the meanings of “about”, “approximately”, “substantially”, and “roughly” may still be implied without specifying “about”, “approximately”, “substantially”, and “roughly”.

In some embodiments of the disclosure, regarding the words such as “connected”, “interconnected”, etc. referring to bonding and connection, unless specifically defined, these words mean that two structures are in direct contact or two structures are not in direct contact, and other structures are provided to be disposed between the two structures. The word for joining and connecting may also include the case where both structures are movable or both structures are fixed. In addition, the word “coupled” may include to any direct or indirect electrical connection means.

In some embodiments of the disclosure, an optical microscopy (OM), a scanning electron microscope (SEM), a film thickness profile measuring instrument (α-step), an elliptical thickness measuring instrument, or other suitable methods may be adopted to measure the area, width, thickness, or height of each element or to measure the distance or spacing between elements. In detail, according to some embodiments, the scanning electron microscope may be used to obtain a cross-sectional structural image of an element to be measured, and to measure the area, width, thickness, or height of each element, or the distance or spacing between elements.

In the disclosure, the definition of roughness determination may be observed by SEM. On an uneven surface, surface undulations with peak-to-valley distance differences of 0.15 micrometers (μm) to 1 μm can be observed. Roughness determination measurements may include using SEM, a transmission electron microscope (TEM), etc., to observe the surface undulation conditions at appropriate and identical magnifications, and compare the undulation conditions by taking a sample of unit length (e.g., 10 μm) to determine its roughness range. Herein, appropriate magnification means that at least one surface may have at least 10 peaks of roughness (Rz) or average roughness (Ra) observed under the magnification.

The electronic device of the disclosure may include but not limited to a display device, an antenna device, a sensing device, or a splicing device. The electronic device may be a bendable or flexible electronic device. The electronic device may include, for example, liquid crystal light emitting diode, the light emitting diode may include, but not limited to, for example, an organic light emitting diode (OLED), a submillimeter light emitting diode (mini LED), a micro light emitting diode (micro LED), a quantum dot (QD) light emitting diode (e.g., QLED or QDLED), fluorescence, phosphor, or other suitable materials, and their materials may be arranged and combined in any way. The antenna device may be but not limited to a liquid crystal antenna, for example. The splicing apparatus may be, for example, a display splicing apparatus or an antenna splicing apparatus, but is not limited thereto. The electronic device may have a peripheral system such as a driving system, a control system, a light source system, a layer system. The electronic device may include electronic units, and the electronic units may include passive components and active components, such as capacitors, resistors, inductors, diodes, transistors, sensors, etc. It should be noted that the electronic device of this disclosure may be various combinations of the above-mentioned devices, but the disclosure is not limited thereto. The electronic device provided by the disclosure may be applied to a power module, a semiconductor packaging device, a display device, a light-emitting device, a backlight device, an antenna device, a sensing device, or a splicing device, but the disclosure is not limited thereto. The electronic device may include but not limited to system on a chip (SoC), system in a package (SiP), antenna in package (AiP), or various combinations of the above devices. Note that the electronic device may be any combination of the foregoing, but is not limited thereto. Hereinafter, an electronic device is provided herein to describe the content of the disclosure, but the disclosure is not limited thereto.

It should be understood that the following embodiments may replace, reorganize, and mix the features in several different embodiments to complete other embodiments without departing from the spirit of the disclosure. As long as the features of the embodiments do not violate the spirit of the disclosure or conflict each other, they may be mixed and matched as desired.

Descriptions of the disclosure are given with reference to the exemplary embodiments illustrated by the accompanying drawings. Wherever possible, the same reference numbers are used in the drawings and the description to refer to the same or like parts.

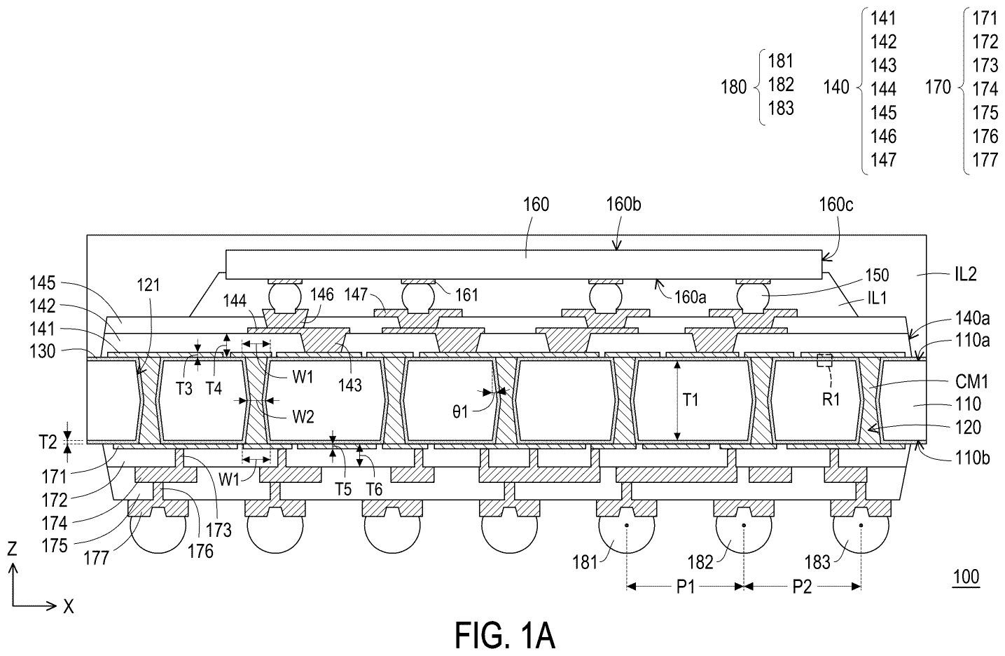

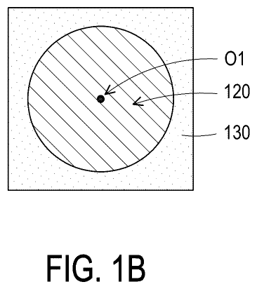

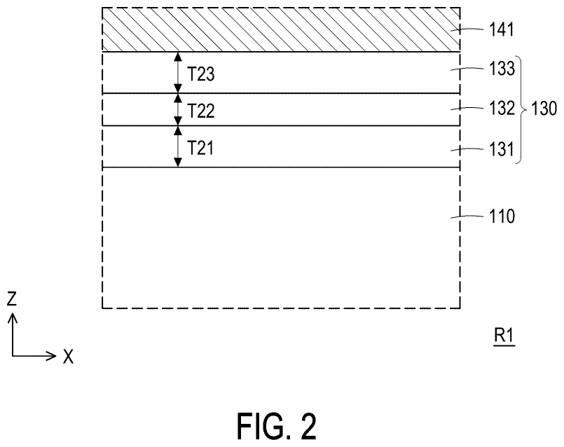

FIG. 1A is a cross-sectional schematic view of an electronic device according to a first embodiment of the disclosure. FIG. 1B is a schematic top view of a through hole in the electronic device of FIG. 1A. FIG. 2 is an enlarged schematic view of a region R1 in FIG. 1A.

With reference to FIG. 1A and FIG. 2 together, an electronic device 100 of this embodiment may include a substrate 110, a through hole 120, a buffer layer 130, a first circuit structure 140, a conductive member 150, an electronic component 160, a second circuit structure 170, a conductive member 180, a first insulating layer IL1, and a second insulating layer IL2. In this embodiment, the electronic device 100 provided by the disclosure may be applied to a power module, a semiconductor packaging device, a display device, a light emitting device, a backlight device, an antenna device, a sensing device, or a splicing device, but the disclosure is not limited thereto.

To be specific, the substrate 110 has a first side 110a and a second side 110b opposite to the first side 110a. In this embodiment, the substrate 110 may include but not limited to borosilicate glass and phosphate glass. According to some embodiments, a coefficient of thermal expansion (CTE) of the substrate 110 may be greater than or equal to 1 ppm/° C. and less than or equal to 10 ppm/° C. In some embodiments, the substrate 110 may also include a rigid substrate, a flexible substrate, or a combination of the foregoing. For instance, a material of the substrate 110 may include but not limited to quartz, sapphire, ceramic, wafer, polycarbonate (PC), polyimide (PI), polyethylene terephthalate (PET), silicon carbide (SiC), gallium nitride (GaN), other suitable substrate materials, or a combination of the foregoing materials. In this embodiment, the substrate 110 has a thickness T1, and the thickness T1 may be 0.03 millimeters (mm) to 10 millimeters, but the disclosure is not limited thereto. The thickness T1 may be a maximum thickness measured in a direction Z of the substrate 110.

In this embodiment, a direction X and the direction Z are different directions, where the direction Z may be a normal direction of the substrate 110 or a normal direction of the electronic device 100, and the direction X is substantially perpendicular to the direction Z, but the disclosure is not limited thereto.

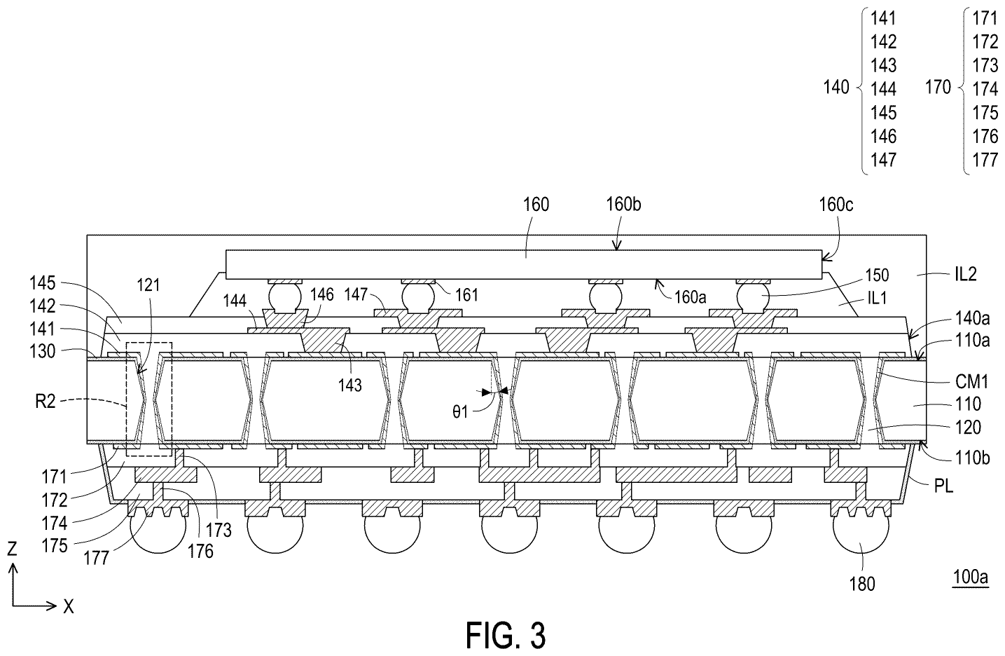

The through hole 120 penetrates the substrate 110. The through hole 120 is filled with a conductive material CM1, so that the through hole 120 may be electrically connected to the first circuit structure 140 and the second circuit structure 170. In this embodiment, the conductive material CM1 may completely fill the through hole 120, but the disclosure is not limited thereto. In some embodiments, the conductive material may also not completely fill the through hole, as shown in FIG. 3.

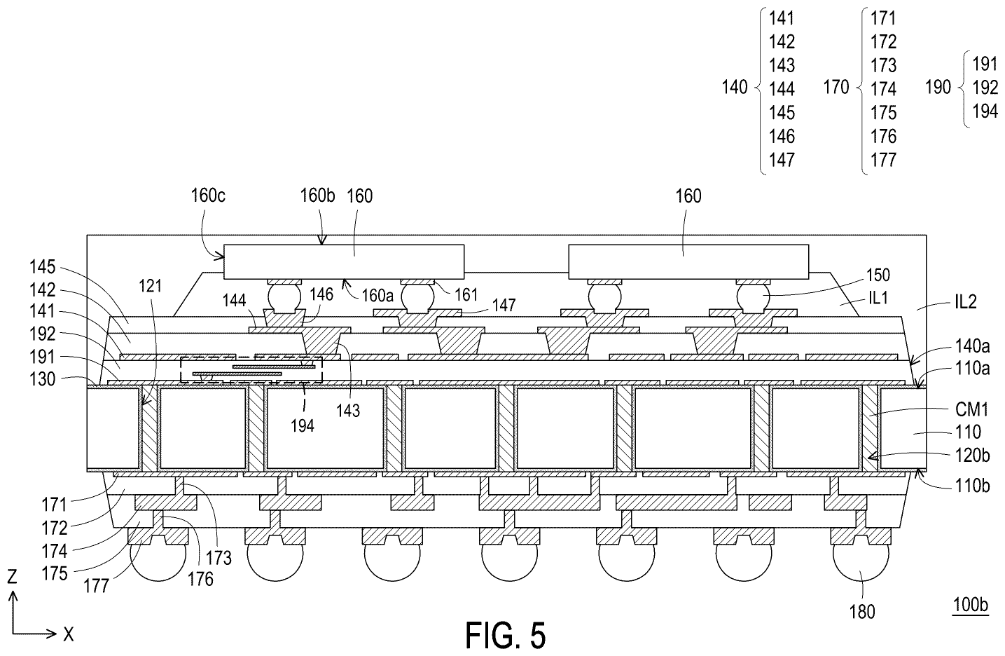

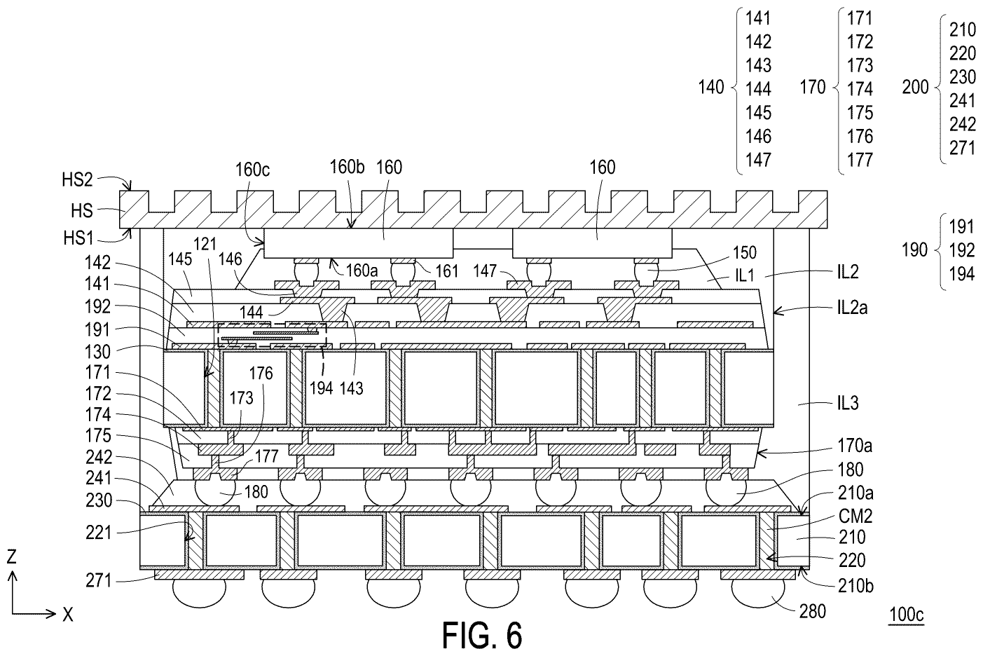

The through hole 120 has a first width W1 and a second width W2. The first width W1 may be a maximum width measured in the direction X on a side of the through hole 120 adjacent to the first circuit structure 140 (or on another side of the through hole 120 adjacent to the second circuit structure 170). The second width W2 may be a minimum width measured in the direction X at a center of the through hole 120. In this embodiment, the first width W1 may be greater than the second width W2, making a shape of the through hole 120 similar to an hourglass, but the disclosure is not limited thereto. In some embodiments, the first width may also be substantially equal to the second width, as shown in FIG. 5 or FIG. 6. In this embodiment, an angle θ1 between an inner wall 121 of the through hole 120 and the direction Z may be between 0 degrees and 20 degrees (i.e., 0<θ1≤20), but the disclosure is not limited thereto. According to some embodiments, roughness of the inner wall 121 may be less than roughness of the first side 110a of the substrate 110, and the roughness of the inner wall 121 may be less than roughness of the second side 110b of the substrate 110, so as to avoid discontinuity or non-uniformity of the conductive material CM1 by controlling the roughness of the inner wall 121, but the disclosure is not limited thereto.

According to some embodiments, in the top view of the through hole shown in FIG. 1B, a contour of the through hole 120 may be approximately circular, but the disclosure is not limited thereto. To be specific, roundness (%) of the through hole 120 may be greater than or equal to 85%, greater than or equal to 90%, or greater than or equal to 95%, but the disclosure is not limited thereto. The roundness of the through hole 120 may be measured, for example, as follows. At least ten diameters passing through a same center O1 of the through hole 120 are obtained. Next, a minimum diameter and a maximum diameter are found. Next, a ratio of the minimum diameter to the maximum diameter is calculated to obtain true roundness (%) of the through hole 120. However, in the disclosure, there is no limitation on the method for measuring the roundness.

The buffer layer 130 is disposed on the first side 110a of the substrate 110, the second side 110b of the substrate 110, and at least a portion of the inner wall 121 of the through hole 120. The buffer layer 130 is disposed between the first side 110a of the substrate 110 and the first circuit structure 140, between the second side 110b of the substrate 110 and the second circuit structure 170, and between the inner wall 121 of the through hole 120 and the conductive material CM1. The buffer layer 130 may contact at least a portion of the first side 110a of the substrate 110, at least a portion of the second side 110b of the substrate 110, and at least a portion of the inner wall 121 of the through hole 120. In this embodiment, the buffer layer 130 may enhance structural strength of the substrate 110 or may enhance an adhesion capability between the substrate 110 and other film layers, so that reliability of the electronic device 100 is improved. For instance, although the material of the substrate 110 (e.g., glass) and the material of a metal layer (e.g., the conductive material CM1, a conductive layer of the first circuit structure 140, or a conductive layer of the second circuit structure 170) have different coefficients of thermal expansion (CTE), by arranging the buffer layer 130 between the substrate 110 and the metal layer, the problems of substrate cracking or interface delamination between the substrate 110 and the metal layer caused by stress generated during the processes of the electronic device 100 (processes such as forming the conductive material CM1 in the through hole 120, forming the first circuit structure 140, or forming the second circuit structure 170) may be decreased.

In this embodiment, the buffer layer 130 has a thickness T2, and the thickness T2 may be from 0.01 micrometers (μm) to 10 micrometers, but the disclosure is not limited thereto. The thickness T2 may be the maximum thickness measured in the direction Z of the buffer layer 130 covering the first side 110a and the second side 110b of the substrate 110, or the thickness T2 may be the maximum thickness measured in the direction X of the buffer layer 130 covering the inner wall 121 of the through hole 120. In this embodiment, a ratio of the thickness T2 of the buffer layer 130 to the width W1 (or width W2) of the through hole 120 may be from 0.02 to 0.2 (i.e., 0.02≤T2/W1≤0.2, or 0.02≤T2/W2≤0.2), so that the design of the buffer layer 130 is sufficient to provide the substrate 110 with a certain level of protection to reduce the problem of substrate 110 cracking, but the disclosure is not limited thereto.

The buffer layer 130 includes a plurality of layers. The buffer layer 130 may include a first sublayer 131, a second sublayer 132, and a third sublayer 133. The first sublayer 131 is disposed between the substrate 110 (or the inner wall 121 of the through hole 120) and the second sublayer 132. The second sublayer 132 is disposed between the first sublayer 131 and the third sublayer 133. The third sublayer 133 is disposed between the second sublayer 132 and a metal material (e.g., the conductive material CM1, a conductive layer 141 of the first circuit structure 140, or a conductive layer 171 of the second circuit structure 170). Although the buffer layer 130 of this embodiment may be a multi-layer stack of 3 sublayers, the disclosure does not limit the number of sublayers in the multi-layer stack of the buffer layer 130, as long as the buffer layer 130 may include at least one organic material layer for contacting the substrate 110 to absorb stress and another inorganic material layer for enhancing an overall Young's modulus of the buffer layer 130.

In this embodiment, the first sublayer 131 and the third sublayer 133 may include organic materials, so that the buffer layer 130 may be used to absorb stress. For instance, the materials of the first sublayer 131 and the third sublayer 133 may include polyimide, parylene, benzocyclobutene (BCB), epoxy, polycarbonate, polyethylene terephthalate, polyethylene naphthalate (PEN), other polymer materials with ductility for absorbing stress, or a combination of the foregoing, but the disclosure is not limited thereto. The organic material of the first sublayer 131 may be the same as or different from the organic material of the third sublayer 133. The second sublayer 132 may include an inorganic material to enhance the strength of the buffer layer 130 and reduce the probability of cracking. For instance, the material of the second sublayer 132 may include silicon nitride (SiNx), silicon oxide (SiOx), other inorganic materials that help improve an overall Young's modulus, or a combination of the foregoing, but the disclosure is not limited thereto.

In this embodiment, the toughness of the first sublayer 131 and the third sublayer 133 of the buffer layer 130 may be from 0.1 kJ/m² to 100 kJ/m², to provide the buffer layer 130 with buffering characteristics, but the disclosure is not limited thereto. The toughness may be measured, for example, using the standard test method for polymer matrix composite materials (ASTM D3039/D3039M). In detail, a member to be subjected to the tensile test is first separated from the electronic device 100. Next, two gage points are pre-marked on the member, where a distance between the two gage points is called the gage length. After that, a tensile machine (e.g., a universal testing machine) is used to stretch the member, so that the gage length gradually elongates during the tensile test process. The toughness may be obtained by calculating an area (using integration) under a stress-strain curve.

In this embodiment, a dissipation factor (Df) of each of the first sublayer 131 and the third sublayer 133 of the buffer layer 130 at a frequency of 5 gigahertz (GHz) or a frequency greater than or equal to 5 GHz may be less than 0.005, to reduce the loss of electrical signals, but the disclosure is not limited thereto. For instance, at a frequency of 5 GHz, the dissipation factor of the third sublayer 133 in contact with the metal material may be less than the dissipation factor of the first sublayer 131, to further reduce the loss of electrical signals, but the disclosure is not limited thereto. According to some embodiments, a difference value between the dissipation factor of the first sublayer 131 and the dissipation factor of the second sublayer 132 may be between 0% and 70% of the dissipation factor of the second sublayer 132, for example, a ratio of an absolute difference value between the dissipation factor of the first sublayer 131 and the dissipation factor of the second sublayer 132 to the dissipation factor of the second sublayer 132. Alternatively, through the above design, insertion loss of the electronic device 100 or the electronic component 160 may be improved, but the disclosure is not limited thereto.

In this embodiment, the Young's modulus of each of the first sublayer 131 and the third sublayer 133 of the buffer layer 130 may be greater than or equal to 20 GPa and less than or equal to 200 GPa, to provide the buffer layer 130 with buffering characteristics, but the disclosure is not limited thereto.

In this embodiment, the first sublayer 131 has a thickness T21, the second sublayer 132 has a thickness T22, and the third sublayer 133 has a thickness T23, but the disclosure is not limited thereto. The thickness T21 of the first sublayer 131 may be the same as or different from the thickness T23 of the third sublayer 133. In this embodiment, a ratio of the thickness T21 of the first sublayer 131 to the thickness T2 of the buffer layer 130 may be from 0.01 to 0.9 (i.e., 0.01≤T21/T2≤0.9), and a ratio of the thickness T23 of the third sublayer 133 to the thickness T2 of the buffer layer 130 may be from 0.01 to 0.9 (i.e., 0.01≤T23/T2≤0.9), but the disclosure is not limited thereto. In this embodiment, a ratio of the thickness T22 of the second sublayer 132 to the thickness T2 of the buffer layer 130 may be from 0.01 to 0.1 (i.e., 0.01≤T22/T2≤0.1), but the disclosure is not limited thereto. Through the multi-layer design of the buffer layer 130, the buffering capability of the substrate under external impact may be enhanced, or the strength of the substrate may be further improved, but the disclosure is not limited thereto.

The first circuit structure 140 is disposed on the first side 110a of the substrate 110, and the first circuit structure 140 may expose a portion of the buffer layer 130 disposed on the first side 110a. The first circuit structure 140 may be electrically connected to the through hole 120, and the first circuit structure 140 may be electrically connected to the second circuit structure 170 through the through hole 120. The first circuit structure 140 includes a conductive layer 141, a dielectric layer 142, a through hole 143, a conductive layer 144, a dielectric layer 145, a through hole 146, and a conductive layer 147. The conductive layer 141 is disposed on the first side 110a of the substrate 110 and on the buffer layer 130. The conductive layer 141 may contact and be electrically connected to the through hole 120. The dielectric layer 142, the conductive layer 144, the dielectric layer 145, and the conductive layer 147 are stacked on the conductive layer 141 in sequence in an alternating manner in the direction Z. The through hole 143 and the through hole 146 are filled with a conductive material. The through hole 143 may penetrate the dielectric layer 142 to be electrically connected to the conductive layer 144 and the conductive layer 141, and the through hole 146 may penetrate the dielectric layer 145 to be electrically connected to the conductive layer 147 and the conductive layer 144. In this embodiment, the conductive layers and the dielectric layers of the first circuit structure 140 may be single-layer or multi-layer stacks. A material of the conductive layers may include copper, titanium, molybdenum, aluminum, nickel, tantalum, gallium, or other suitable conductive materials. Further, a material of the dielectric layers may include polyimide, photosensitive polyimide (PSPI), polybenzoxazole (PBO), epoxy resin, polymer, benzocyclobutene (BCB), ajinomoto build-up layer (ABF), silicon oxide (SiOx), silicon nitride (SiNx), silicon oxynitride (SiNxOy), or other suitable dielectric materials, but the disclosure is not limited thereto.

The conductive layer 141, the conductive layer 144, and the conductive layer 147 have a thickness T3, and the thickness T3 may be 0.5 mm to 12 mm, but the disclosure is not limited thereto. The thickness T3 may be a maximum thickness measured in the direction Z for the conductive layer 141, the conductive layer 144, or the conductive layer 147. According to some embodiments, the thicknesses of the conductive layer 141, the conductive layer 144, and the conductive layer 147 may be the same or different. For instance, the thickness of the conductive layer 147 may be greater than the thickness of the conductive layer 141.

The dielectric layer 142 and the dielectric layer 145 have a thickness T4, and the thickness T4 may be 5 mm to 15 mm, but the disclosure is not limited thereto. The thickness T4 may be a maximum thickness measured in the direction Z for the dielectric layer 142 or the dielectric layer 145. In this embodiment, the thickness T4 of the dielectric layer 142 and the dielectric layer 145 may be greater than the thickness T2 of the buffer layer 130 (i.e., T4>T2), but the disclosure is not limited thereto. According to some embodiments, the thicknesses of the dielectric layer 142 and the dielectric layer 145 may be the same or different. For instance, the thickness of the dielectric layer 145 may be greater than the thickness of the dielectric layer 142.

In this embodiment, the first circuit structure 140 and the second circuit structure 170 may be redistribution layers (RDLs) and include at least one conductive layer and at least one dielectric layer (in FIG. 1A, 3 conductive layers and 2 dielectric layers are schematically shown, but the disclosure is not limited thereto). The redistribution layer may allow for circuit redistribution and/or further increase a circuit fan-out area. The redistribution layer may be used for electrically connecting different electronic components. The redistribution layer may extend connections to wider pitches or redistribute connections to another connection with different pitches, and/or the redistribution layer may serve as a substrate for electrical interface wiring between one connection and another. For instance, the pitch between two adjacent contact pads at one end of the redistribution structure contacting the electronic component may be less than or equal to the pitch between two adjacent contact pads at one end of the redistribution structure away from the electronic component. Therefore, the redistribution structure may adjust the circuit fan-out condition or electrically connect the circuit structure/electronic component having the first pitch to the circuit structure/electronic component having the second pitch, but the disclosure is not limited thereto. The steps of forming the redistribution layer may include providing a stack of at least one conductive layer and at least one dielectric layer, and the method of forming the redistribution layer may include processes such as photolithography, etching, surface treatment, laser, electroplating, chemical plating, deposition, atomic layer deposition, etc. The surface treatment may include roughening or activating the surface of the dielectric layer or the conductive layer to enhance the adhesion capability of the dielectric layer or conductive layer. For instance, increasing the surface roughness may enhance the bonding strength with subsequent film layers.

The conductive member 150 is disposed on the conductive layer 147 of the first circuit structure 140. The conductive member 150 may contact and be electrically connected to the conductive layer 147 of the first circuit structure 140. A material of the conductive member 150 may include tin, copper, nickel, gold, silver, gallium, a combination of the foregoing, an alloy of the foregoing, or other suitable materials, but the disclosure is not limited thereto. For instance, the conductive member 150 may be a solder ball, a tin ball, or a copper pillar (Cu pillar), but the disclosure is not limited thereto. The design where the thickness of the conductive layer 147 may be greater than the thickness of the conductive layer 141 helps to enhance the bonding strength after the conductive layer 147 is bonded to the conductive member 150, but the disclosure is not limited thereto.

The electronic component 160 is disposed on the first circuit structure 140 and on the conductive member 150. The electronic component 160 has an active surface 160a, a back surface 160b, and a side surface 160c. The active surface 160a faces the first circuit structure 140, the active surface 160a and the back surface 160b are opposite to each other, and the side surface 160c connects the active surface 160a and the back surface 160b. The electronic component 160 includes a pad 161 disposed on the active surface 160a. The pad 161 of the electronic component 160 may be electrically connected to the conductive layer 147 of the first circuit structure 140 through the conductive member 150. The electronic component 160 may include a passive component or an active component, such as a chip, a known good die (KGD), a semiconductor structure, a silicon photonic chip, a diode, a transistor, a capacitor, a resistor, an inductor, etc., but the disclosure is not limited thereto.

The second circuit structure 170 is disposed on the second side 110b of the substrate 110, and the second circuit structure 170 is disposed between the substrate 110 and the conductive member 180. The second circuit structure 170 may be electrically connected to the through hole 120. The second circuit structure 170 includes a conductive layer 171, a dielectric layer 172, a through hole 173, a conductive layer 174, a dielectric layer 175, a through hole 176, and a conductive layer 177. The conductive layer 171 is disposed below the second side 110b of the substrate 110. The conductive layer 171 may contact and be electrically connected to the through hole 120. The dielectric layer 172, the conductive layer 174, the dielectric layer 175, and the conductive layer 177 are stacked below the conductive layer 171 in sequence in an alternating manner in the direction Z. The through hole 173 and the through hole 176 are filled with a conductive material. The through hole 173 may penetrate the dielectric layer 172 to be electrically connected to the conductive layer 174 and the conductive layer 171, and the through hole 176 may penetrate the dielectric layer 175 to be electrically connected to the conductive layer 177 and the conductive layer 174. In this embodiment, the conductive layers and dielectric layers of the second circuit structure 170 may be single-layer or multi-layer stacks, and the materials of the conductive layers and dielectric layers may be the same as or similar to those of the conductive layers and dielectric layers in the first circuit structure 140, so description thereof is not repeated herein.

The conductive layer 171, the conductive layer 174, and the conductive layer 177 have a thickness T5, and the thickness T5 may be 0.5 mm to 12 mm, but the disclosure is not limited thereto. The thickness T5 may be a maximum thickness measured in the direction Z for the conductive layer 171, the conductive layer 174, or the conductive layer 177. According to some embodiments, the thickness of the conductive layer 171, the conductive layer 174, and the conductive layer 177 may be the same as or different from the thickness of the conductive layer 141, the conductive layer 144, and the conductive layer 147.

The dielectric layer 172 and the dielectric layer 175 have a thickness T6, and the thickness T6 may be 5 mm to 15 mm, but the disclosure is not limited thereto. The thickness T6 may be a maximum thickness measured in the direction Z for the dielectric layer 172 or the dielectric layer 175. In this embodiment, the thickness T4 of the dielectric layer 172 or the dielectric layer 175 may be greater than the thickness T2 of the buffer layer 130 (i.e., T6>T2), but the disclosure is not limited thereto. According to some embodiments, the thickness of the dielectric layer 172 and the dielectric layer 175 may be the same as or different from the thickness of the dielectric layer 142 and the dielectric layer 145. For instance, the thickness of the dielectric layer 175 may be greater than the thickness of the dielectric layer 145.

The conductive member 180 is disposed on the second side 110b of the substrate 110. The conductive member 180 may be electrically connected to the electronic component 160 through the through hole 120 and the first circuit structure 140. The conductive member 180 may be a solder ball or a tin ball, but the disclosure is not limited thereto. Further, in this embodiment, the conductive member 180 may be disposed below the conductive layer 177 of the second circuit structure 170, and the conductive member 180 may be electrically connected to the through hole 120 through the second circuit structure 170, but the disclosure is not limited thereto. In some embodiments, the second circuit structure may not be disposed depending on the requirements or design needs, so that the conductive member may contact or be electrically connected to the through hole through other components.

In some embodiments, the pitch between two adjacent conductive members 180 may be the same or different. For instance, the conductive member 180 may include a conductive member 181, a conductive member 182, and a conductive member 183. A pitch P1 is provided between the conductive member 181 and the conductive member 182, and a pitch P2 is provided between the conductive member 182 and the conductive member 183. The pitch P1 may be a minimum distance measured in the direction X between a center point of the conductive member 181 and a center point of the conductive member 182, and the pitch P2 may be a minimum distance measured in the direction X between the center point of the conductive member 182 and a center point of the conductive member 183. In some embodiments, the pitch P1 may be less than the pitch P2 (i.e., P1<P2), but the disclosure is not limited thereto.

The first insulating layer IL1 is disposed between the electronic component 160 and the first circuit structure 140 to fix the electronic component 160. The first insulating layer IL1 may surround the conductive member 150 and the conductive layer 147. In the cross-sectional view of the electronic device 100, the first insulating layer IL1 may at least contact a side surface of the conductive member 150 and a side surface of the conductive layer 147. In this embodiment, the first insulating layer IL1 may include an organic material or an inorganic material. For instance, the organic material may be an underfill or other suitable polymer materials, and the inorganic material may include silicon oxide, silicon nitride, or other suitable inorganic materials, but the disclosure is not limited thereto.

The second insulating layer IL2 is disposed on the first side 110a of the substrate 110, and the second insulating layer IL2 may surround the electronic component 160 and the first circuit structure 140, to protect the electronic component 160 or isolate moisture. In the cross-sectional view of the electronic device 100, the second insulating layer IL2 may at least contact the side surface 160c of the electronic component 160 and the side surface 140a of the first circuit structure 140. The second insulating layer IL2 may contact the buffer layer 130. In this embodiment, the second insulating layer IL2 may include an organic material or an inorganic material. For instance, the organic material may be a molding layer, and the inorganic material may include silicon oxide, silicon nitride, or other suitable materials, but the disclosure is not limited thereto.

In this embodiment, a manufacturing method of the electronic device 100 may include but not limited to the following steps and step sequence. First, the substrate 110 is provided, where the substrate 110 has the first side 110a and the second side 110b opposite to the first side 110a. Next, the substrate 110 is drilled by, for example, laser modification or etching to form the through hole 120 that penetrates the substrate 110. Next, the buffer layer 130 is formed so that the buffer layer 130 can cover and contact the first side 110a, the second side 110b, and the inner wall 121 of the through hole 120. Next, the conductive material CM1 is formed in the through hole 120 by, for example, electroplating or chemical deposition, so that the buffer layer 130 disposed in the through hole 120 is located between the conductive material CM1 and the substrate 110. Next, the first circuit structure 140 and the second circuit structure 170 are formed on the first side 110a and the second side 110b respectively by processes such as photolithography, etching, surface treatment, laser, and electroplating, so that the buffer layer 130 disposed on the first side 110a is located between the first circuit structure 140 and the substrate 110 and the buffer layer 130 disposed on the second side 110b is located between the second circuit structure 170 and the substrate 110. Next, the electronic component 160 is bonded to the first circuit structure 140 through the conductive member 150. Next, the conductive member 180 is formed under the second circuit structure 170, so that the conductive member 180 may be bonded to a carrier or a circuit board in a subsequent process, as shown in FIG. 6. Next, the first insulating layer IL1 is formed between the electronic component 160 and the first circuit structure 140. Next, the second insulating layer IL2 is formed, so that the second insulating layer IL2 may surround the electronic component 160 and the first circuit structure 140.

In this embodiment, the manufacturing method of the electronic device 100 may be applied in, for example, wafer-level package (WLP) or panel-level package (PLP) processes, and may be a redistribution layer first (RDL first) fabrication method with either chip first or chip last approach.

Other embodiments are described for illustration in the following. It should be noted that the reference numerals and a part of the contents in the previous embodiments are used in the following embodiments, in which identical reference numerals indicate identical or similar components, and repeated description of the same technical content is omitted. Please refer to the description of the previous embodiments for the omitted content, which will not be repeated hereinafter.

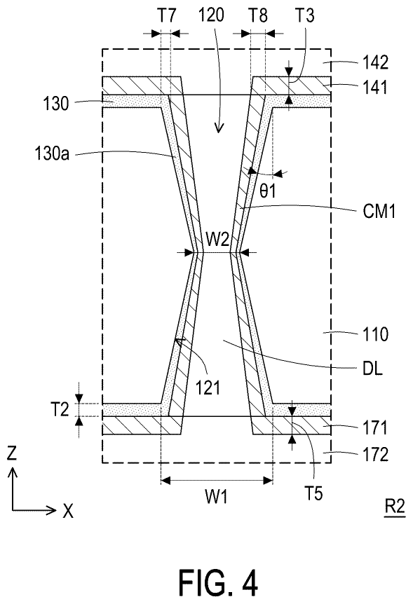

FIG. 3 is a cross-sectional schematic view of an electronic device according to a second embodiment of the disclosure. FIG. 4 is an enlarged schematic view of a region R2 in FIG. 3. With reference to FIG. 3 to FIG. 4 and FIG. 1A to FIG. 2 together, an electronic device 100a of this embodiment is similar to the electronic device 100 in FIG. 1A to FIG. 2, but the difference therebetween is that: in the electronic device 100a of this embodiment, the thickness T2 of the buffer layer 130 outside the through hole 120 is different from a thickness T7 of a buffer layer 130a inside the through hole 120, and the conductive material CM1 does not completely fill the through hole 120.

To be specific, with reference to FIG. 3 and FIG. 4, the thickness T2 of the buffer layer 130 may be the maximum thickness measured in the direction Z of the buffer layer 130 covering the first side 110a and the second side 110b of the substrate 110. The thickness T7 of the buffer layer 130a may be the thickness measured in the direction X of the buffer layer 130a covering the inner wall 121 of the through hole 120. In this embodiment, the thickness T2 of the buffer layer 130 may be greater than the thickness T7 of the buffer layer 130a, but the disclosure is not limited thereto. Further, in this embodiment, the thickness T7 of the buffer layer 130a may gradually decrease from the side of the through hole 120 adjacent to the first circuit structure 140 (or the other side of the through hole 120 adjacent to the second circuit structure 170) towards the center of the through hole 120, so that the thickness T7 of the buffer layer 130a presents a gradient state, but the disclosure is not limited thereto.

The conductive material CM1 is disposed on the inner wall 121 of the through hole 120, so that the buffer layer 130a is located between the inner wall 121 of the through hole 120 and the conductive material CM1. The conductive material CM1 has a thickness T8, and the thickness T8 may be the thickness of the conductive material CMI measured in the direction X. In this embodiment, the thickness T3 of the conductive layer 141 (or the thickness T5 of the conductive layer 171) may be greater than the thickness T8 of the conductive material CM1, but the disclosure is not limited thereto. Further, in this embodiment, the thickness T8 of the conductive material CM1 may gradually decrease from the side of the through hole 120 adjacent to the first circuit structure 140 (or the other side of the through hole 120 adjacent to the second circuit structure 170) towards the center of the through hole 120, so that the thickness T8 of the conductive material CM1 presents a gradient state, but the disclosure is not limited thereto.

In addition, some conductive layers 177 may have a groove design, for example, the outer conductive layer 177 may have a groove design. This allows part of the conductive member 180 to fill into the groove of the conductive layer 177, enhancing the bonding capability between the conductive member 180 and the conductive layer 177. Since the electronic device may be further bonded to other external devices through the conductive member 180, the groove design of the conductive layer 177 may enhance the bonding strength between the electronic device and external components, but the disclosure is not limited thereto.

In this embodiment, the electronic device 100a further includes a passivation layer PL. The passivation layer PL is disposed on a side edge of the dielectric layer 172, a side edge of the dielectric layer 175, and a surface of the dielectric layer 175 facing the conductive member 180. The passivation layer PL may or may not contact the conductive layer 177. The passivation layer PL may include an organic material or an inorganic material. The passivation layer PL may include a single-layer structure or a multi-layer structure, where the passivation layer PL may have the same structure as the buffer layer 130. The passivation layer PL may be used to block moisture and to reduce the impact of moisture on the second circuit structure 170, but the disclosure is not limited thereto.

In this embodiment, the electronic device 100a further includes a dielectric layer DL. The dielectric layer DL is disposed inside the through hole 120 to fill the through hole 120 and to allow the conductive material CM1 to be located between the buffer layer 130a and the dielectric layer DL.

FIG. 5 is a cross-sectional schematic view of an electronic device according to a third embodiment of the disclosure. With reference to FIG. 5 and FIG. 1A to FIG. 2 together, an electronic device 100b of this embodiment is similar to the electronic device 100 in FIG. 1A to FIG. 2, but the difference therebetween is that: the electronic device 100b of this embodiment further includes a component integration layer 190, and a shape of a through hole 120b may be columnar.

To be specific, with reference to FIG. 5, the component integration layer 190 is disposed on the first side 110a of the substrate 110 and is disposed between the first circuit structure 140 and the substrate 110. The component integration layer 190 includes a conductive layer 191, a dielectric layer 192, and a component 194. The conductive layer 191 is disposed on the buffer layer 130, the dielectric layer 192 is disposed on the conductive layer 191, and the component 194 is disposed within the dielectric layer 192. In this embodiment, the component 194 may overlap the electronic component 160 in the direction Z, thereby shortening a signal transmission path between the component 194 and the electronic component 160, which in turn may reduce signal loss or achieve energy-saving effects.

In this embodiment, the conductive layer 191 and the dielectric layer 192 of the component integration layer 190 may be a single layer or multiple layer stack. A material of the conductive layer may include copper, titanium, molybdenum, aluminum or other suitable conductive materials. A material of the dielectric layer may include polyimide, photosensitive polyimide, polybenzoxazole, epoxy resin, polymer, ajinomoto build-up film, silicon oxide, silicon nitride, or other suitable dielectric materials, but the disclosure is not limited thereto. The material of the dielectric layer 192 of the component integration layer 190 may be the same as or different from the material of the dielectric layer of the first circuit structure 140.

In this embodiment, the component integration layer 190 includes at least one component 194, for example, may include, an active component, a passive component, or other suitable components. In some embodiments, the component 194 may at least partially overlap the electronic component 160, thereby shortening the signal transmission path, but the disclosure is not limited thereto. In some embodiments, the active component may be a transistor or a thin-film transistor. In some embodiments, the passive component may be a capacitor, a resistor, or an inductor.

In this embodiment, a first width W1 of the through hole 120b may be substantially equal to a second width W2, and the shape of the through hole 120b may be columnar, but the disclosure is not limited thereto.

FIG. 6 is a cross-sectional schematic view of an electronic device according to a fourth embodiment of the disclosure. With reference to FIG. 6 and FIG. 5 together, an electronic device 10c of this embodiment is similar to the electronic device 10b in FIG. 5, but the difference therebetween is that: the electronic device 100c of this embodiment further includes a heat sink HS, a carrier 200, a conductive member 280, and a third insulating layer IL3.

To be specific, with reference to FIG. 6, the second insulating layer IL2 exposes the back side 160b of the electronic component 160. The heat sink HS is disposed on the electronic component 160 and the second insulating layer IL2. The heat sink HS has a first side HS1 and a second side HS2 opposite to each other. The first side HS1 of the heat sink HS may contact the back side 160b of the electronic component 160 to conduct the heat generated by the electronic component 160 to the external environment. The second side HS2 of the heat sink HS may have fins and grooves to enhance the heat dissipation effect.

The carrier 200 is disposed on the second side 110b of the substrate 110. The carrier 200 may be bonded to the substrate 110 through the conductive member 180, such that the conductive member 180 is disposed between the second side 110b of the substrate 110 and the carrier 200. The carrier 200 may include a substrate 210, a through hole 220, a buffer layer 230, a conductive material CM2, a conductive layer 241, a dielectric layer 242, and a conductive layer 271.

To be specific, the substrate 210 has a first side 210a and a second side 210b opposite to each other, with the first side 210a facing the substrate 110 and the second side 210b facing away from the substrate 110. The through hole 220 penetrates the substrate 210. The buffer layer 230 is disposed on the first side 210a of the substrate 210, the second side 210b of the substrate 210, and the inner wall 221 of the through hole 220. The conductive material CM2 fills the through hole 220. The conductive layer 241 is disposed on the first side 210a of the substrate 210, the conductive layer 241 is located between the conductive member 180 and the through hole 220, and the conductive layer 241 may be electrically connected to the conductive member 180 and the through hole 220. The dielectric layer 242 is disposed on the conductive layer 241, and the dielectric layer 242 may surround the conductive layer 241 and the conductive member 180. The conductive layer 271 and the conductive member 280 are disposed on the second side 210b of the substrate 210, the conductive layer 271 is located between the through hole 220 and the conductive member 280, and the conductive layer 271 may be electrically connected to the through hole 220 and the conductive member 280.

In this embodiment, the conductive member 180 may be electrically connected to the conductive member 280 through the conductive layer 241, the through hole 220, and the conductive layer 271. The electronic component 160 may be electrically connected to the carrier 200 through the conductive member 150, the first circuit structure 140, the through hole 120, the second circuit structure 170, and the conductive member 180.

The third insulating layer IL3 is disposed on the first side 210a of the substrate 210, and the third insulating layer IL3 may surround the second insulating layer IL2, the second circuit structure 170, and the dielectric layer 242 to protect the electronic component 160 or isolate moisture. In the cross-sectional view of the electronic device 100c, the third insulating layer IL3 may at least contact the side surface IL2a of the second insulating layer IL2, the side surface 170a of the second circuit structure 170, and the side surface of the dielectric layer 242. The third insulating layer IL3 may also contact a part of the buffer layer 230 of the carrier 200. In this embodiment, the third insulating layer IL3 may include an organic material or an inorganic material. For instance, the organic material may be a molding layer, and the inorganic material may include silicon oxide, silicon nitride, or other suitable materials, but the disclosure is not limited thereto.

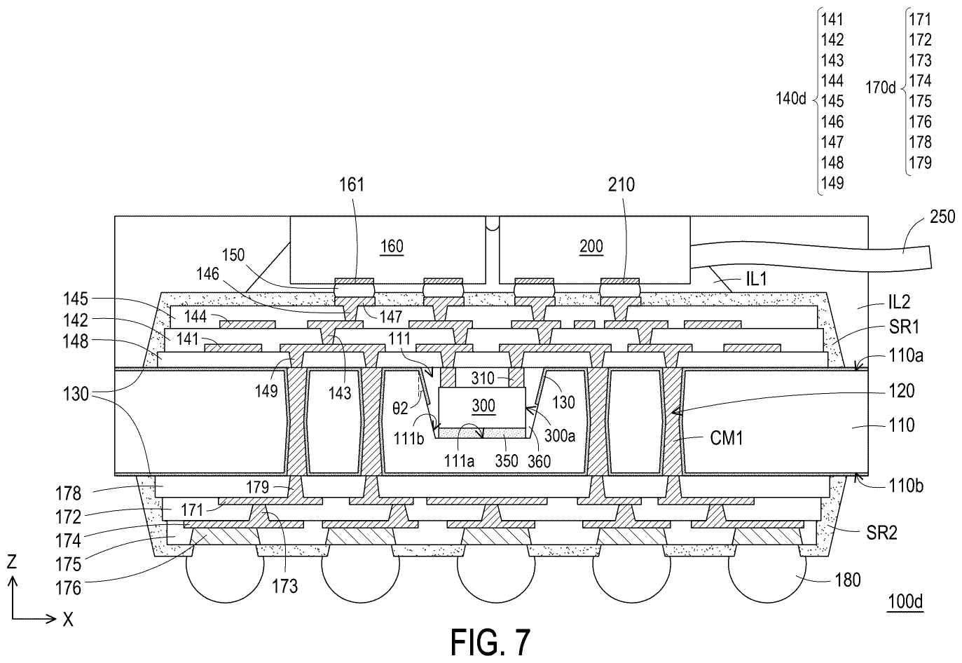

FIG. 7 is a cross-sectional schematic view of an electronic device according to a fifth embodiment of the disclosure. With reference to FIG. 7 and FIG. 1A to FIG. 2 together, an electronic device 100d of this embodiment is similar to the electronic device 100 in FIG. 1A to FIG. 2, but the difference therebetween is that: the electronic device 100d of this embodiment further includes an electronic component 200, an optical fiber 250, an electronic component 300, a solder resist layer SR1, and a solder resist layer SR2, and the substrate 110 includes a groove 111 recessed into the first side 110a.

To be specific, with reference to FIG. 7, a first circuit structure 140d further includes a dielectric layer 148 and a through hole 149. The dielectric layer 148 is disposed between the dielectric layer 142 and the first side 110a of the substrate 110. The through hole 149 is filled with a conductive material, and the through hole 149 may penetrate the dielectric layer 148 to electrically connected to the conductive layer 141 and the through hole 120.

A second circuit structure 170d further includes a dielectric layer 178 and a through hole 179. The dielectric layer 178 is disposed between the second side 110b of the substrate 110 and the dielectric layer 172. The through hole 179 is filled with a conductive material, and the through hole 179 may penetrate the dielectric layer 178 to electrically connected to the through hole 120 and the conductive layer 171.

The solder resist layer SR1 may cover and surround the first circuit structure 140d to protect the first circuit structure 140d by blocking external moisture and oxygen or preventing the first circuit structure 140d from being affected during the fabrication of the conductive member 150. The solder resist layer SR2 may cover and surround the second circuit structure 170d to protect the second circuit structure 170d by blocking external moisture and oxygen or preventing the second circuit structure 170d from being affected during the fabrication of the conductive member 180.

The electronic component 200 is disposed on the first circuit structure 140d and the conductive member 150, and the electronic component 200 is adjacent to the electronic component 160. The pad 210 of the electronic component 200 may be electrically connected to the conductive layer 147 of the first circuit structure 140d through the conductive member 150. In this embodiment, the electronic component 200 may be a photonic IC (PIC), and the electronic component 200 may be electrically connected to the optical fiber 250, but the disclosure is not limited thereto.

The groove 111 may correspond to and overlap the electronic component 200 and the electronic component 160 in the direction Z. The groove 111 has a bottom surface 111a and an inner wall 111b. The buffer layer 130 may cover a portion of the inner wall 111b of the groove 111. An adhesive layer 350 is disposed on the bottom surface 111a of the groove 111. An underfill 360 is filled in the groove 111. According to some embodiments, an angle θ2 between the inner wall 111b of the groove 111 and the direction Z may be between 20 degrees and 60 degrees (i.e., 20≤θ2≤60) to facilitate easier placement of the electronic component 300, but the disclosure is not limited thereto.

The electronic component 300 is embedded and fixed in the groove 111 through the adhesive layer 350. The electronic component 300 may correspond to and overlap the electronic component 200 and the electronic component 160 in the direction Z. A pad 310 of the electronic component 300 may be electrically connected to the through hole 149 of the first circuit structure 140d. In this embodiment, the electronic component 300 may be a connector for processing signals between the electronic component 160 and the electronic component 200, but the disclosure is not limited thereto. According to some embodiments, the adhesive layer 350 may further contact a side surface 300a of the electronic component 300 to further secure the electronic component 300, but the disclosure is not limited thereto.

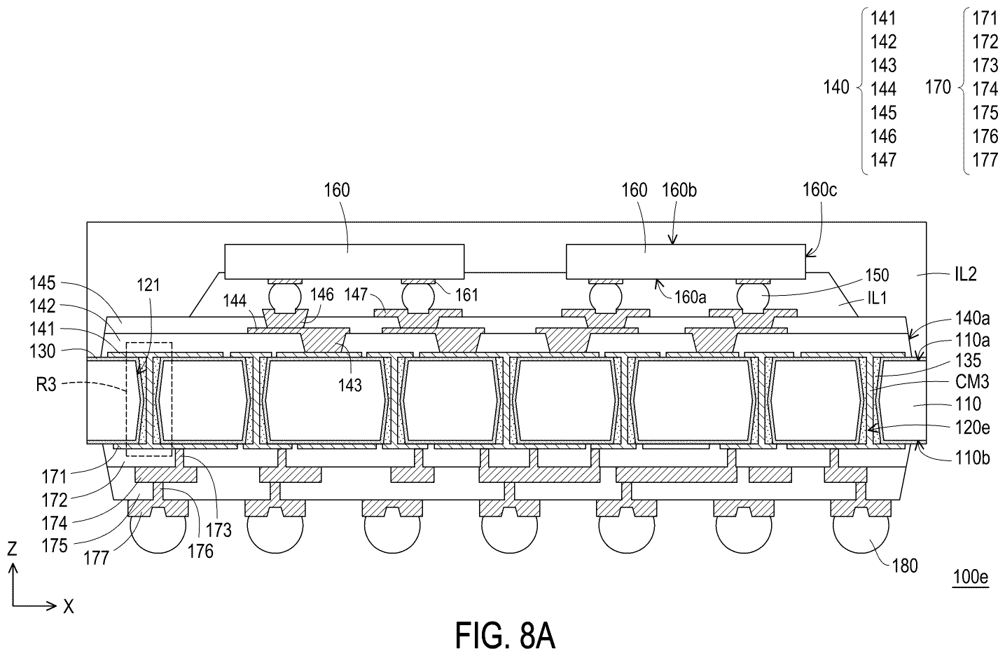

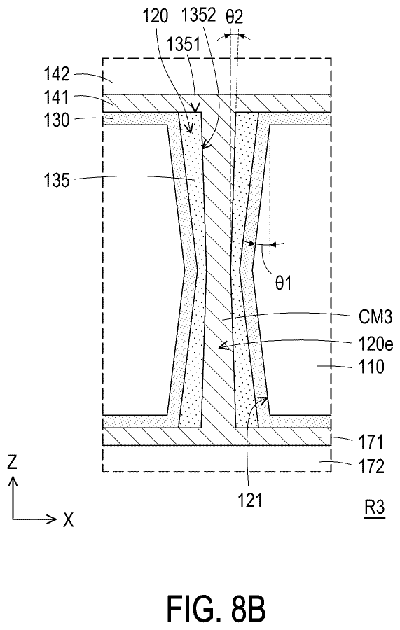

FIG. 8A is a cross-sectional schematic view of an electronic device according to a sixth embodiment of the disclosure. FIG. 8B is an enlarged schematic view of a region R3 in FIG. 8A. With reference to FIG. 8A to FIG. 8B and FIG. 1A to FIG. 2 together, an electronic device 100e of this embodiment is similar to the electronic device 100 in FIG. 1A to FIG. 2, but the difference therebetween is that: the electronic device 100e of this embodiment further includes an adjustment layer 135 and a through hole 120e.

To be specific, with reference to FIG. 8A and FIG. 8B, the adjustment layer 135 is disposed on the buffer layer 130 within the through hole 120, such that the buffer layer 130 within the through hole 120 is located between the substrate 110 and the adjustment layer 135. The adjustment layer 135 may cover and contact the buffer layer 130.

The through hole 120e penetrates the substrate 110 and the adjustment layer 135. The through hole 120e is filled with a conductive material CM3, such that the adjustment layer 135 is located between the buffer layer 130 within the through hole 120 and the conductive material CM3, and the through hole 120e may be electrically connected to the first circuit structure 140 and the second circuit structure 170.

In this embodiment, the adjustment layer 135 may be used to adjust shapes of the conductive material CM3 and the through hole 120e, so that the through hole 120e filled with the conductive material CM3 may be columnar or elongated columnar, and the shape of the through hole 120e may be close to rectangular. The impact on signal transmission is thereby lowered.

In this embodiment, the angle θ1 between the inner wall 121 of the through hole 120 and the direction Z may be greater than or equal to 3 degrees and less than or equal to 20 degrees (i.e., 3≤θ1≤20), but the disclosure is not limited thereto.

The adjustment layer 135 has a surface 1351 and a side surface 1352 adjacent to each other. The surface 1351 faces the conductive layer 141 of the first circuit structure 140, and the side surface 1352 faces the conductive material CM3. In this embodiment, an angle between the surface 1351 and the side surface 1352 may be approximately a right angle, and an angle θ3 between the side surface 1352 and the direction Z may be greater than or equal to 0 degrees and less than or equal to 3 degrees (i.e., 0≤θ3≤3), but the disclosure is not limited thereto.

In this embodiment, a manufacturing method of the adjustment layer 135 may include but not limited to the following steps and step sequence. First, after the through hole 120 and the buffer layer 130 are formed, an adjustment material is filled into the through hole 120. Next, a portion of the adjustment material is removed by using a method such as laser to form the adjustment layer 135 and the through hole 120e.

In view of the foregoing, in the electronic device provided by the embodiments of the disclosure, the buffer layer is disposed on the first side of the substrate, the second side of the substrate, and an inner wall of the through hole. In this way, the structural strength of the substrate may be enhanced or the adhesion capability between the substrate and other film layers may be enhanced, so that reliability of the electronic device may be improved. For instance, through the arrangement of the buffer layer, the problems of substrate cracking or interface delamination between the substrate and the metal layer caused by stress generated during the processes of the electronic device (processes such as forming the conductive material in the through hole, forming the first circuit structure, or forming the second circuit structure) may be decreased.

Finally, it is worth noting that the foregoing embodiments are merely described to illustrate the technical means of the disclosure and should not be construed as limitations of the disclosure. Even though the foregoing embodiments are referenced to provide detailed description of the disclosure, people having ordinary skill in the art should understand that various modifications and variations can be made to the technical means in the disclosed embodiments, or equivalent replacements may be made for part or all of the technical features; nevertheless, it is intended that the modifications, variations, and replacements shall not make the nature of the technical means to depart from the scope of the technical means of the embodiments of the disclosure.

What is claimed is:

1. An electronic device, comprising:
a substrate comprising a first side and a second side opposite to the first side;
a through hole penetrating the substrate;
a buffer layer disposed on the first side of the substrate, the second side of the substrate, and an inner wall of the through hole;
a first circuit structure disposed on the first side; and
an electronic component disposed on the first circuit structure,
wherein the buffer layer comprises a plurality of layers.

2. The electronic device according to claim 1, wherein the buffer layer comprises:
a first sublayer comprising an organic material; and
a second sublayer comprising an inorganic material,
wherein the first sublayer is disposed between the substrate and the second sublayer.

3. The electronic device according to claim 2, wherein the buffer layer further comprises:
a third sublayer comprising an organic material,
wherein the second sublayer is disposed between the first sublayer and the third sublayer.

4. The electronic device according to claim 3, wherein toughness of each of the first sublayer and the third sublayer is 0.1 kJ/m² to 100 kJ/m².

5. The electronic device according to claim 3, wherein a dissipation factor of each of the first sublayer and the third sublayer is less than 0.005.

6. The electronic device according to claim 3, wherein Young's modulus of each of the first sublayer and the third sublayer is greater than or equal to 20 GPa and less than or equal to 200 GPa.

7. The electronic device according to claim 2, wherein a ratio of a thickness of the first sublayer to a thickness of the buffer layer is 0.01 to 0.9.

8. The electronic device according to claim 2, wherein a ratio of a thickness of the second sublayer to a thickness of the buffer layer is 0.01 to 0.1.

9. The electronic device according to claim 1, wherein a ratio of a thickness of the buffer layer to a thickness of the through hole is 0.02 to 0.2.

10. The electronic device according to claim 1, wherein the substrate comprises glass.

11. The electronic device according to claim 1, wherein the first circuit structure comprises a dielectric layer, and a thickness of the dielectric layer is greater than a thickness of the buffer layer.

12. The electronic device according to claim 1, wherein the electronic component is electrically connected to the through hole through the first circuit structure.

13. The electronic device according to claim 1, further comprising:
a first insulating layer disposed between the electronic component and the first circuit structure.

14. The electronic device according to claim 1, further comprising:
a second insulating layer surrounding the electronic component and the first circuit structure.

15. The electronic device according to claim 1, further comprising:
a second circuit structure disposed on the second side and electrically connected to the first circuit structure through the through hole.

16. The electronic device according to claim 1, wherein a thickness of the buffer layer outside the through hole is different from a thickness of the buffer layer inside the through hole.

17. The electronic device according to claim 1, further comprising:
a component integration layer disposed between the first circuit structure and the substrate,
wherein the component integration layer comprises a component overlapping the electronic component.

18. The electronic device according to claim 1, further comprising:
a heat sink disposed on and contacting the electronic component.

19. The electronic device according to claim 1, further comprising:
another electronic component disposed in a groove of the substrate and overlapping the electronic component.

20. The electronic device according to claim 1, further comprising:
an adjustment layer disposed in the through hole,
wherein the buffer layer is located between the substrate and the adjustment layer.
